(19) United States
(12) Patent Application Publication
(10) Pub. No.: US 2010/0102761 A1
(43) Pub. Date: Apr. 29, 2010

(54) Organic Radiation-Emitting Device, Use Thereof and a Method of Producing the Device

(76) Inventors: Norwin Von Malm, Thumhausen (DE); Markus Klein, Tegernheim (DE); Hendrik Jan Bolink, Valencia (ES)

Correspondence Address: SLATER & MATSIL, L.L.P., 17950 PRESTON RD, SUITE 1000, DALLAS, TX, 75252-5793, US

(21) Appl. No.: 12/593,238

(22) PCT Filed: Mar. 27, 2008
(86) PCT No.: PCT/DE08/00539

§ 371 Date: Sep. 25, 2009

(30) Foreign Application Priority Data
Mar. 30, 2007 (DE) 10 2007 015 468.4

(51) Int. Cl. H01L 51/54; H01L 51/56; H05B 37/00

(52) U.S. Cl. 315/363; 257/40; 438/29; 257/E51.027; 257/E21.158

(57) ABSTRACT

The invention discloses an organic radiation-emitting device which includes a substrate, and at least one radiation-emitting organic layer, which is arranged on the substrate between a first and a second electrode layer. A first charge carrier transport layer, which includes a first charge carrier transport material and a first salt, is arranged between the first electrode layer and the radiation-emitting organic layer.

This patent application is a national phase filing under section 371 of PCT/DE2008/000539, filed Mar. 27, 2008, which claims the priority of German patent application 10 2007 015 468.4, filed Mar. 30, 2007, each of which is incorporated herein by reference in its entirety.

### BACKGROUND

Polymer light-emitting electrochemical cells comprising an electroluminescent layer in which an ion conductor is simultaneously present are known from the publication “Polymer Light-Emitting Electrochemical Cells: In Situ Formation of a Light-Emitting p-n Junction” found in the Journal of the American Chemical Society 1996, 118, pp. 3922 to 3929. When an electrical field is applied to two electrodes arranged adjacent to the electroluminescent layer, ion migration occurs in the electrical field and visible light is emitted (electroluminescence).

### SUMMARY

Some embodiments of the invention provide further organic radiation-emitting devices.

One embodiment of the invention provides an organic radiation-emitting device which includes a substrate, and at least one radiation-emitting organic layer, which is arranged on the substrate between a first and a second electrode layer. A first charge carrier transport layer, which comprises a first charge carrier transport material and a first salt, is arranged between the first electrode layer and the radiation-emitting organic layer.

When a voltage is applied to the first and second electrode layers of such an organic radiation-emitting device, charge carriers, for example, defect electrons, so-called “holes”, and negative charge carriers, electrons, may be injected by the two electrode layers into the radiation-emitting organic layer. In so doing, the first charge carrier transport layer transports the charge carriers injected from the first electrode layer to the radiation-emitting organic layer. Transport of the charge carriers generated by the first electrode into the organic, radiation-emitting layer may take place primarily via the charge carrier transport material of the first charge carrier transport layer. The inventors have established that such a device comprises an elevated current density and an elevated luminance relative to other radiation-emitting devices, whose charge carrier transport layers comprise no salt.

Compounds are here used as the first salt that comprise anions and cations, at least one ion possibly being an organic ion. It is also possible for the salt to comprise both organic cations and organic anions. Preferably, the first salt comprises an organic ion and an inorganic counterion. The first salt may also comprise organometallic salts.

In a further embodiment of the invention, the first salt is redox stable. The consequence of this is that, when a voltage is applied to the first and second electrode layers, charge carriers, for example, electrodes and defect electrons (“holes”) are indeed injected from these electrode layers into the organic, radiation-emitting layer but the ions of the first salt are themselves neither oxidized nor reduced and thus retain their original oxidation numbers. Transport of the charge carriers of the first electrode layer thus proceeds predominantly or exclusively via the charge carrier transport material of the first charge carrier transport layer and not via the ions of the first salt.

According to a further embodiment of the invention, the first salt is a constituent of a first ion conductor.

The inventors have established that a charge carrier transport layer comprising an ion conductor has a lower injection barrier for the charge carriers emitted from the first electrode layer than a charge carrier transport layer not containing an ion conductor.

In the case of an ion conductor, when an electrical voltage is applied to the first and second electrode layers under the influence of the electrical field, directed migration of electrically charged ions takes place. When electrically charged ions migrate in a solid acting as an ion conductor, smaller ions, which also interact less strongly with the solid, such as, for example, lithium, migrate via lattice voids while larger ions, for example, larger organic ions, mainly migrate via lattice sites (hopping conduction). Ion conduction in solids is, in this case, a thermally active process, in which the ions have to overcome or tunnel through a potential barrier in order to transport charges by means of hopping conduction. In one embodiment of the invention, the ions of the first salt thus migrate in the electrical field if a voltage is applied to the first and second electrode layers. In relation to ion conduction, reference is made to the full content of the entry “Ion conductors” in the Römpp Chemie Lexikon, 9th expanded edition, Georg Thieme Verlag 1995.

In particular, the first charge carrier transport material and the first salt together form the first ion conductor, such that, for example, the ions of the first salt move in a matrix formed by the first charge carrier transport material when an electrical field is applied.

In a further embodiment of the invention the first ion conductor may comprise a polymer. This polymer may, for example, form a matrix in which the ions of the first salt may migrate when a voltage is applied. The polymer may, in particular, be an organic polymer comprising functional groups, which may interact with the ions of the first salt. The polymer may, for example, comprise ether groups and thus form a polyether compound. In this case, the ether groups may coordinate the ions of the first salt, for example, the cations. It is then possible for the ions to be inserted into the polymer matrix and for “ion-polymer coordination complexes,” for example, to be formed. Such crystalline ion-polymer complexes may be particularly well suited to forming organic polymer ion conductors. An example of a polyether compound is, for example, polyethylene oxide of the general formula:

H—[—O—CH₂—CH₂—]ₙ—OH

The degree of polymerization n may here reach >100000, the higher molecular weight solid polymers being known as polyethylene oxides and the low molecular weight polymers being known as polyethylene glycols. Polyether compounds may form complexes with a plurality of organic and inorganic first salts. Within these ion conductors ion migration may then arise by way of hopping conduction when a voltage is applied to the first and second electrode layers.

In a further embodiment of the invention, in addition to the polymer the ion conductor comprises an organic salt as a first salt which has been inserted in the polymer. Such ion conductors are particularly suitable as ion conductors in charge carrier transport layers which likewise comprise organic charge carrier transport materials.

The inventors assume that ion conductors as constituents of a charge carrier transport layer may reduce the barrier for the injection of charge carriers from the first electrode layer into the first charge carrier transport layer. This could inter alia be attributed to an increased accumulation of ionic charges at the boundary surface between the first electrode layer and the first charge carrier transport layer when a voltage is applied, wherein the injection barrier could be reduced thereby and thus charge carriers could also be in a position to tunnel through this injection barrier. It is also possible for an accumulation of charge carriers at the boundary surface between the first electrode layer and the first charge carrier transport layer to reduce the work function for the charge carriers from the first electrode layer, resulting in an increased current density and luminance for the organic radiation-emitting device. In the case of the first electrode layer being connected as a cathode, the Fermi level of the first electrode layer may thus be raised by the presence of the first salt, which may result in a reduction in the work function for the electrons.

In a further embodiment of the invention, the first salt is selected in such a way that both the anions and the cations of the salt are mobile in the electrical field. In this respect, the salt may be selected in such a way that either the cation or the anion migrates markedly more quickly than the respective counterion. However, an embodiment is also possible in which the cation and anion have a comparable migration rate in the electrical field.

As a result of the migration of ions of a charge in the charge carrier transport layer in the direction of the, for example, adjacent electrode, charge compression corresponding to the charge of the ions at the boundary area between charge transport layer and electrode layer is possible.

A “Schottky barrier” may arise in the boundary area between an electrode layer and charge carrier transport layer. In contrast to the pn-junction in a conventional semiconductor diode, this is not formed by the semiconductor-semiconductor junction, but rather generally by a semiconductor-metal junction.

This “Schottky barrier” results in the work function of the charge carriers from the electrode into the charge carrier transport layer being lowered.

Furthermore, the polymer may be redox stable and thus neither oxidized nor reduced upon application of a voltage to the first and second electrode layers.

For example, for the first ion conductor poly(ethylene oxide) (PEO) may be used as the polymer and lithium trifluoroalkylsulfonate, for example, Li⁺F₃CSO₄⁻, as the first salt. Further examples are complexes of PEO with LiAsF₆, KSCN, NaBPh₄ or ZnCl₂.

Furthermore, it is also possible to use polyelectrolytes as ion conductors. Polyelectrolytes are, for example, polymers with ionically dissociable groups which may be a constituent or a substituent of the polymer chain. In this case, above all the counterions to the polymeric ions, which are present for charge balancing, are suitable for transporting charges in the polyelectrolyte matrix by means of the hopping mechanism. It is then possible for the polymeric constituent of the polyelectrolytes to be a polymer anion, for example, and then for cations to be inserted into the anionic polymer matrix for charge balancing. In this case, the cations may then migrate particularly well in the polyelectrolyte matrix by means of hopping conduction upon application of a voltage. It is furthermore also possible to use cationically charged polymeric constituents which comprise as counterions anions which have been inserted in the polymer matrix. In this case the anions may then above all migrate in the cationically charged polymer matrix by means of the hopping mechanism upon application of an electrical field to the first and second electrode layers.

Possible examples of polyelectrolytes are, for example, poly(sodium styrenesulfonate) of the following general formula:

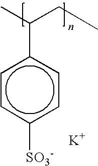

the degree of polymerization n possibly being selected in such a way that the molar mass is greater than 1,000,000 g/mol and K⁺ standing for the countercation.

Another possibility is the use of polyacrylates of, for example, the following general formula:

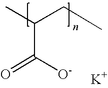

In both cases an anionic polymer matrix is present, into which cations have been inserted for charge balancing.

Furthermore, polyelectrolytes may also be used as ion conductors which comprise only a small number of ionic groups and are so-called ionomers. Sulfonated tetrafluorethylene copolymers, which are sold, for example, under the brand name Nafion®, may for example be used. In the case of such polymers, the sulfonates form ionically dissociable groups, such that a negatively charged polymer matrix is present, into which cations have been inserted for charge balancing. Possible cations may, for example, be alkali or alkaline earth metal cations, for example, lithium, magnesium or sodium.

In a further embodiment of the invention the first charge carrier transport layer comprises a first organic charge carrier transport material. The charge carrier transport material is in this case suitable, as a result of its chemical structure, for transporting negative charges such as electrons or positive charges such as defect electrons or holes.

Charge carrier transport materials for transporting positive charge carriers, or “hole transport materials”, may, for example, comprise electron donor groups such as, for example, amines. Possible examples of hole transport materials are arylamines, such as for example 1,1-bis[4-(4-methylstyryl)phenyl-4-tolylaminophenyl]cyclohexane, 5′[4-[bis(4-ethylphenyl(amino]-N,N,N′,N′-tetrakis(4-ethylphenyl)1,1′,3′1″-terphenyl]-4,4″-diamine (EFTP), N,N′-bis(1-naphthalene)-N,N′-diphenyl-4,4′-phenylamine (NPPDA), N,N,N′,N′-tetrakis(m-methylphenyl)-1,3-diaminobenzene (TAPC), bis(ditolylaminostyryl)benzene (TASB), N,N-diphenyl-N,N′-bis(3-methylphenyl)-(1,1′-biphenyl)-4,4′-diamine (TPD), N,N′,N″,N″-tetrakis(4-methylphenyl)-1,1′-biphenyl)-4,4′-diamine (TTB), triphenylamine (TPA) and tri-p-tolylamine (TTA). Further examples of hole transport materials are enamines, hydrazones, oxadiazoles and oxazoles, phthalocyanines, pyrazolines and poly(N-vinylcarbazole) (PVK).

It is also possible to use polymeric hole transport materials such as, for example, polyethylene dioxythiophene (PEDOT) with polystyrenesulfonic acid (PPS).

Charge carrier transport materials for transporting negative charge carriers, or “electron transport materials”, may, for example, comprise electron acceptor groups, so-called “electron-attracting groups”, such as, for example, anthraquinones, diphenoquinones, indans, 2,4,7-trinitro-9-fluorenone and mixtures thereof with PVK, and sulfones.

It is also possible to use mixtures of different charge carrier transport materials in a charge carrier transport layer.

If the first electrode layer is connected as the anode, the first charge carrier transport material of the first charge carrier transport layer comprises a hole transport material whilst, if it is connected as the cathode, the first charge carrier transport material of the first charge carrier transport layer comprises an electron transport material.

Due to the presence of the first salt in the charge carrier transport layer, doping of the first charge carrier transport material with p- or n-dopants may be dispensed with, depending on whether it is a hole transport material or an electron transport material. These dopants are often chemically reactive and may therefore have a negative influence on the service life of the device. In contrast, the first salt is preferably chemically inert and redox stable, as already described above.

In further exemplary embodiments of the invention, in which the first charge carrier transport layer comprises a first charge carrier transport material and a first ion conductor comprising the first salt, the first salt may, if the first electrode layer is connected as the anode, comprise anions which have a greater mobility in the charge carrier transport layer than the cations of the first salt. In this case, when a voltage is then applied to the boundary surface between the anode and the hole transport layer, anion accumulation may occur. Due to their lower mobility, however, the non-advantageous migration of the cations to the cathode which might possibly take place through the radiation-emitting organic layer does not take place or takes place only to a lesser degree. As a rule, the anions, which exhibit elevated mobility, only enter into slight interaction with the hole transport layer and are also frequently smaller than the cations, which are not so mobile. One example of such a first salt is tetraalkylammonium salts with inorganic small anions such as PF₆⁻ or AsF₆⁻, which may, for example, be used with arylamines as first hole transport materials.

Likewise, the first salt may also comprise cations, which exhibit greater mobility in the first charge carrier transport layer than the anions, if the first electrode layer is connected as the cathode. In this case, when a voltage is applied, cations may accumulate at the boundary surface between the cathode and the electron transport layer, anion migration conversely not taking place, or only taking place to a greatly restricted degree. Examples of such first salts are alkylsulfonates (for example, trifluoroalkylsulfonates) with small cations, such as, for example, lithium.

According to a further embodiment of the invention, the charge carrier transport material may also simultaneously adopt the function of a first ion conductor.

The radiation-emitting organic layer may contain materials which are selected from electroluminescent low molecular weight (“small molecule”) compounds and electroluminescent polymers, such that the radiation-emitting device may, in particular, be an organic, light-emitting device (OLED). In OLEDs, radiation is emitted (electroluminescence) as a result of a recombination of electrodes and holes in the radiation-emitting organic layer.

Examples of electroluminescent polymers are poly(1,4-phenylene vinylene) (PPV) and the derivatives thereof, polyquinolines and the derivatives thereof, copolymers of polyquinoline with p-phenylenes, poly(p-phenylene-2,6-benzobisthiazole), poly(p-phenylene-2,6-benzobisoxazole), poly-p-phenylene-2,6-benzimidazole) and the derivatives thereof, poly(arylenes) with aryl residues such as naphthalene, anthracene, furylene, thienylene, oxadiazole, poly-p-phenylene and the derivatives thereof such as for example poly(9,9-dialkylfluorene).

Low molecular weight, electroluminescent compounds are, for example, tris(8-hydroxyquinolinato)aluminum (Alq₃); 1,3-bis(N,N-dimethylaminophenyl)-1,3,4-oxidazole (OXD-8); oxo-bis(2-methyl-8-quinolinato)aluminum; bis(2-methyl-8-hydroxyquinolinato)aluminum; bis(hydroxybenzoquinolinato)beryllium (BeQ2); bis(diphenylvinyl)biphenylene (DPVBI) and arylamine-substituted distyrylarylene (DSA amines).

Furthermore hole or electron transport layers may be present as charge carrier transport layers between both the anode and the cathode of the radiation-emitting devices. A second charge carrier transport layer is then likewise present between the second electrode layer and the radiation-emitting organic layer. This likewise comprises a second salt, which may also be a constituent of a second ion conductor. This ion conductor may again be constructed in a manner similar to the first ion conductor already described above.

The radiation emitted by the radiation-emitting organic device may lie in the ultraviolet to infrared wavelength range, preferably in the visible wavelength range of approximately 400 nm to 800 nm.

The radiation-emitting organic device may take the form, for example, of a “bottom-emitting” device, which radiates the radiation generated outwards through the substrate. If the first electrode layer is arranged on the substrate, the radiation generated in the radiation-emitting organic layer is then coupled out through the first charge carrier transport layer, the first electrode layer and then the substrate. The first charge carrier transport layer, the first electrode layer and the substrate are then transparent to the emitted electromagnetic radiation.

Alternatively or in addition, the radiation-emitting organic device may also take the form of a “top-emitting” device, in which the emitted radiation is radiated through the electrode layer more remote from the substrate and an encapsulation located over the layer arrangement of electrode layers, the radiation-emitting organic layer and the charge carrier transport layer. In this case, the electrode layer, through which the radiation is coupled out, and the encapsulation are transparent to the emitted radiation.

The radiation-emitting devices may be used, for example, for lighting applications in lighting devices. Use is also possible in indicator devices such as, for example, display devices.

A further embodiment of the invention also provides a method of producing the radiation-emitting device. A layer arrangement that includes a radiation-emitting organic layer, a first electrode layer, a first charge carrier transport layer and second electrode layer is formed on the substrate. The first charge carrier transport layer is produced between the first electrode layer and the radiation-emitting organic layer and includes a first charge carrier transport material and a first salt.

If the first electrode layer is formed on the substrate, the first electrode layer can be formed on the substrate, and the first charge carrier transport layer can be formed on the first electrode layer. The radiation-emitting organic layer can be formed on the first charge carrier transport layer, and the second electrode layer can be formed on the radiation-emitting organic layer.

In forming the first charge carrier transport layer a mixture of the first charge carrier transport material and the first ion conductor may be applied. If both the first ion conductor and the first charge carrier transport material comprise polymeric constituents, both may be applied from solution by means of wet-chemical methods for example also together with the first salt. The application methods may for example be printing methods, spin coating or dip coating. The printing methods may for example be ink jet printing methods, roll printing methods or screen printing methods.

In addition, in forming the first charge carrier transport layer, low molecular weight materials may also be used as charge carrier transport materials and as constituents of the first ion conductor. In this case, these constituents may also be applied from the gas phase, for example together with the first salt.

In the two above-stated cases for forming the first charge carrier transport layer, however, it is also possible firstly to produce a layer of the charge carrier transport materials and the polymeric or low molecular weight constituents of the first ion conductor and only then to apply the first salt, wherein this may then diffuse into the already present layer.

Alternatively, it is also possible firstly to produce the second electrode layer on the substrate and then in turn to construct the functional layer arrangement over the substrate. In this case, the second electrode layer is formed on the substrate, and the radiation-emitting organic layer is formed on the second electrode layer. The first charge carrier transport layer is formed on the radiation-emitting organic layer, and the first electrode layer is formed on the first charge carrier transport layer.

Forming the radiation-emitting organic layer, the possible configurations stated above for the analogous method of forming the first charge carrier transport layer are also feasible.

### BRIEF DESCRIPTION OF THE DRAWINGS

A number of embodiments of the invention are explained in greater detail below with reference to the Figures and exemplary embodiments. In all the Figures, identical reference numerals here denote identical elements:

FIG. 1 shows in cross-section an embodiment of a device according to the invention with a first charge carrier transport layer;

FIG. 2 shows a cross-section of a further embodiment of a device according to the invention with a first and a second charge carrier transport layer;

FIG. 3 shows a device with encapsulation; and

FIG. 4 shows a diagram which illustrates the current density and luminance of different devices.

### DETAILED DESCRIPTION OF ILLUSTRATIVE EMBODIMENTS

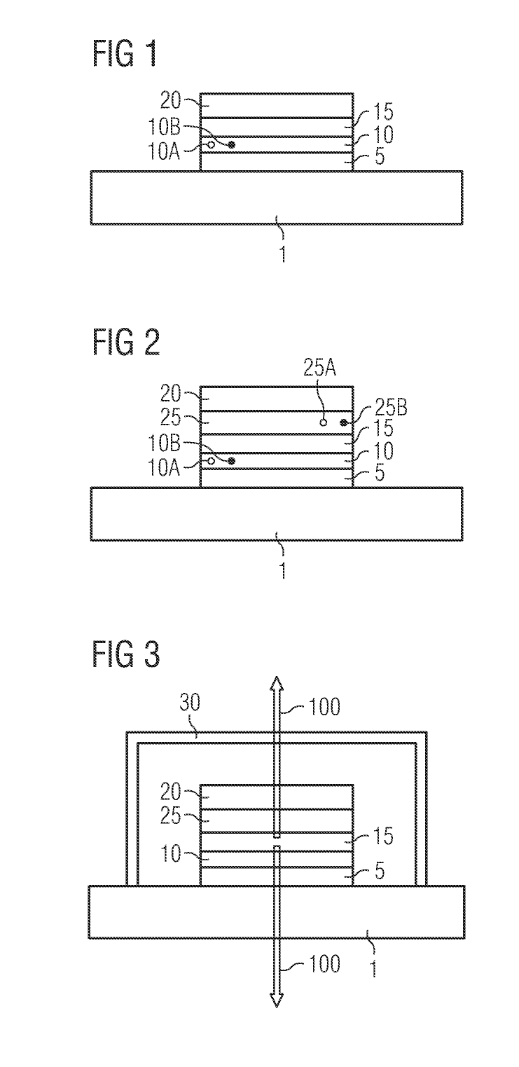

FIG. 1 shows an embodiment of a radiation-emitting device according to the invention, in which a first electrode layer 5, a first charge carrier transport layer 10, a radiation-emitting organic layer 15 and a second electrode layer 20 are arranged on a substrate 1. It is indicated schematically that the first charge carrier transport layer 10 comprises a first charge carrier transport material 10A and a first salt 10B. As a result of the presence of the first salt 10B, such a device exhibits elevated luminance and current density in the organic functional layers.

FIG. 2 shows a further embodiment of a radiation-emitting device according to the invention, in which, in addition to the first charge carrier transport layer 10, a second charge carrier transport layer 25 is also present. This comprises, shown schematically, a second charge carrier transport material 25A and a second salt 25B. Because of the first charge carrier transport layer 10 and the second charge carrier transport layer 25, injection of charge carriers from the two electrode layers into the radiation-emitting organic layer 15 is simplified.

FIG. 3 shows a further embodiment of a radiation-emitting device according to the invention with encapsulation 30 over the organic functional layer arrangement. The two arrows 100 indicate that the emitted radiation may be coupled out of the device both through the transparent encapsulation 30 and through the transparent substrate 1.

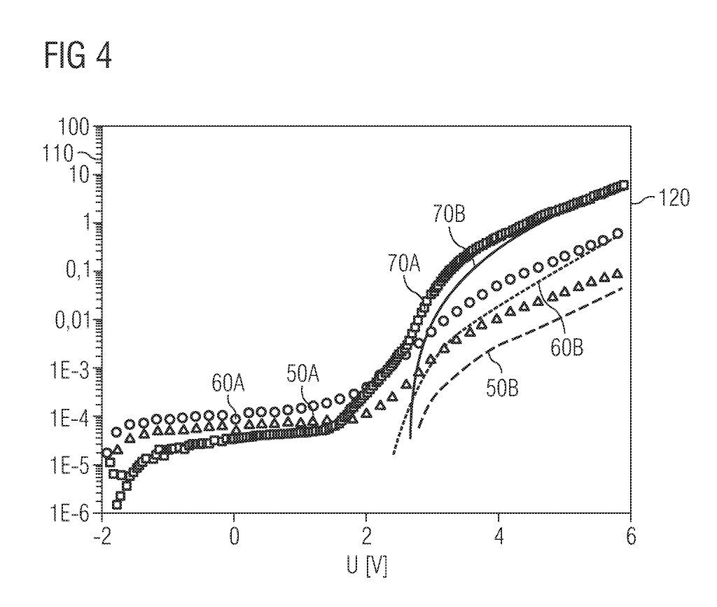

FIG. 4 shows a diagram that indicates the luminances and current densities of various radiation-emitting devices as a function of the quantity of the first salt in a polyarylamine hole transport layer. The axis labeled 110 indicates the current density J in A/m² and the axis labeled 120 indicates the luminance in Cd/m². The applied voltage in V is plotted on the bottom axis. The curves labeled with A numbers show the current densities and the curves provided with B numbers show the respective associated luminances. It should be noted that a device in which no first salt is present in the hole transport layer (curve labeled 50A for current density and curve labeled 50B for luminance) displays a lower current density and luminance than a device which comprises 2 wt. % of a first salt in the hole transport layer (curve labeled 60A for current density and curve labeled 60B for luminance). The device with 2 wt. % of the first salt in turn displays a lower current density and luminance than an OLED device with 5 wt. % salt (curve labeled 70A for current density and curve labeled 70B for luminance). It is thus clear that the current density and luminance increase as salt concentration increases.

### Exemplary Embodiment

Glass sheets coated with indium-tin oxide (ITO) are used as substrates with first electrode layers and cleaned. Then a polyarylamine, pTPD, obtainable from American Dye Source under the name ADS254BE is dissolved in chlorobenzene. In a typical example 40 mg of pTPD are dissolved in 2 ml of chlorobenzene and 0.113 mg of an organic salt tetrabutylammonium hexafluorophosphate, dissolved in chlorobenzene, are added to this solution. The solution is then filtered through a 0.45 μm PTFE filter. With this mixture a thin layer is then applied to the ITO glass substrate by means of spin coating at 2000 rpm. The thickness of the applied layers is determined with the aid of an Ambios XP1 Profilometer. A layer of an electroluminescent polymer, for example, a polyfluorene derivative, obtainable from American Dye Source under the name ADS136BE, is applied by spin coating a solution of the polymer in toluene. Because of the insolubility of the pTPD layer in toluene, the hole transport layer does not intermix with the electroluminescent layer. A cathode consisting of 5 nm Ba and 80 nm silver was applied thereto.

The current density and luminance in relation to the voltage is determined by means of a Keithley 2400 current meter and a photodiode, which is connected to a Keithley 6485 picoampmeter, the photocurrent being calibrated by means of a Minolta LS100. An Avantes luminance spectrometer is used to determine the EL spectra of the OLEDs.

Different quantities of the organic salt are used in production of the hole transport layer for different OLEDs and the respective current densities and luminances are determined, the result being the diagram shown in FIG. 4.

The invention is not restricted by the description given with reference to the exemplary embodiments. Rather, the invention encompasses any novel feature and any combination of features, including, in particular, any combination of features in the claims, even if this feature or this combination is not itself explicitly indicated in the claims or exemplary embodiments.

1. An organic radiation-emitting device, comprising:
a substrate layer;
a first electrode layer;
a second electrode layer;
at least one radiation-emitting organic layer arranged on the substrate between the first electrode layer and the second electrode layer; and
a first charge carrier transport layer arranged between the first electrode layer and the at least one radiation-emitting organic layer, the first charge carrier transport layer comprising a first charge carrier transport material and a first salt.

2. The organic radiation-emitting device according to claim 1, wherein the first salt comprises an organic salt.

3. The organic radiation-emitting device according to claim 1, wherein the first salt is redox stable.

4. The organic radiation-emitting device according to claim 1, wherein the first salt is a constituent of a first ion conductor.

5. The organic radiation-emitting device according to claim 4, wherein the first ion conductor is selected from the group consisting of polyelectrolytes and ionomers.

6. The organic radiation-emitting device according to claim 4, wherein the first ion conductor comprises a polymer.

7. The organic radiation-emitting device according to claim 6, wherein the polymer comprises a polyether compound.

8. The organic radiation-emitting device according to claim 6, wherein the first ion conductor comprises a complex of the polymer with the first salt.

9. The organic radiation-emitting device according to claim 6, wherein the polymer is redox stable.

10. The organic radiation-emitting device according to claim 6, wherein the first ion conductor comprises poly(ethylene oxide) as the polymer and lithium trifluoroalkylsulfonate as the first salt.

11. The organic radiation-emitting device according to claim 1,
wherein the first electrode layer comprises an anode, and
wherein anions exhibit greater mobility in the first charge carrier transport layer than cations.

12. The organic radiation-emitting device according to claim 11, wherein the first charge carrier transport layer comprises a hole transport material as the first charge carrier transport material.

13. The organic radiation-emitting device according to claim 1,
wherein the first electrode layer comprises a cathode, and
wherein cations have a greater mobility in the first charge carrier transport layer than anions.

14. The organic radiation-emitting device according to claim 13, wherein the first charge carrier transport layer comprises an electrode transport material as the first charge carrier transport layer.

15. The organic radiation-emitting device according to claim 1, wherein the radiation-emitting organic layer contains materials that are selected from the group consisting of electroluminescent low molecular weight (“small molecule”) compounds and electroluminescent polymers.

16. The organic radiation-emitting device according to claim 1, further comprising a second charge carrier transport layer arranged between the second electrode layer and the at least one radiation-emitting organic layer, the second charge carrier transport layer comprising a second charge carrier transport material and a second salt.

17. The organic radiation-emitting device according to claim 16, wherein the second charge carrier transport layer comprises a second ion conductor.

18. The organic radiation-emitting device according to claim 1,
wherein the first electrode layer is arranged on the substrate, and
wherein the first electrode layer, the first charge carrier transport layer and the substrate are transparent to emitted radiation of the at least one radiation-emitting organic layer.

19. The organic radiation-emitting device according to claim 1, further comprising:
encapsulation arranged over the at least one radiation-emitting organic layer, the first electrode layer and the second electrode layer on the substrate,
wherein the electrode layers arranged in the vicinity of the encapsulation and the encapsulation are transparent to emitted radiation of the at least one radiation-emitting organic layer.

20. The organic radiation-emitting device according to claim 1, wherein the first salt comprises a material such that, when an electrical field is applied, both anions and cations of the first salt are mobile in the first charge carrier transport layer.

21. The organic radiation-emitting device according to claim 1, wherein a Schottky barrier is formed by migration of ions of the first salt.

22. A method of using an organic radiation-emitting device for lighting applications, the method comprising:
providing an organic radiation-emitting device that comprises a substrate, at least one radiation-emitting organic layer arranged on the substrate between a first electrode layer and a second electrode layer, and a first charge carrier transport layer arranged between the first electrode layer and the radiation-emitting organic layer, the first charge carrier transport layer comprising a first charge carrier transport material and a first salt; and
applying a voltage between the first electrode layer and the second electrode layer.

23. A method of producing an organic radiation-emitting device, having the method comprising:
providing a substrate;
forming a layer arrangement over the substrate, the layer arrangement comprising a radiation-emitting organic layer, a first electrode layer, a first charge carrier transport layer and a second electrode layer,
wherein the first charge carrier transport layer is formed between the first electrode layer and the radiation-emitting organic layer and comprises a first charge carrier transport material and a first salt.

24. The method according to claim 23, wherein forming the layer arrangement comprises:
forming the first electrode layer on the substrate;
forming the first charge carrier transport layer on the first electrode
forming the radiation-emitting organic layer on the first charge carrier transport layer; and
forming the second electrode layer on the radiation-emitting organic layer.

25. The method according to claim 24,
wherein the first charge carrier transport layer comprises a first ion conductor,
wherein forming the first charge carrier transport layer comprises applying a mixture of the first charge carrier transport material and the first ion conductor to the first electrode layer.

26. The method according to claim 25,
wherein polymers are used as the first charge carrier transport material and as a constituent of the first ion conductor, and
wherein forming the first charge carrier transport layer comprises applying a solution of a mixture of the first charge carrier transport material and polymers of the first ion conductor.

27. The method according to claim 25,
wherein low molecular weight substances are used as the first charge carrier transport material and as a constituent of the first ion conductor, and
wherein forming the first charge carrier transport layer comprises applying from a gas phase the first charge carrier transport material and the low molecular weight substances of the first ion conductor.

28. The method according to claim 24,
wherein a first ion conductor is used as the first charge carrier transport layer, the first ion conductor comprising an organic polymer and the first salt, and
wherein forming the first charge carrier transport layer comprises applying the organic polymer together with the first charge carrier transport material, a layer being formed and then a solution of the first salt being applied to the layer.

29. The method according to claim 23 wherein forming the layer arrangement comprises:
forming the second electrode layer on the substrate;
producing forming the radiation-emitting organic layer on the second electrode layer;
forming the first charge carrier transport layer on the radiation-emitting organic layer; and
forming the first electrode layer on the first charge carrier transport layer.

30. The method according to claim 23, further comprising forming, a second charge carrier transport layer between the second electrode layer and the radiation-emitting organic layer.
